(19) United States
(12) Patent Application Publication
(10) Pub. No.: US 2023/0085356 A1
(43) Pub. Date: Mar. 16, 2023

(54) SEMICONDUCTOR DEVICE

(71) Applicant: Kioxia Corporation, Tokyo (JP)

(72) Inventors: Ryo SUEMITSU, Yokkaichi (JP); Takashi OHASHI, Yokkaichi (JP)

(21) Appl. No.: 17/687,202

(22) Filed: Mar. 4, 2022

(30) Foreign Application Priority Data
Sep. 15, 2021 (JP) 2021-150451

(51) Int. Cl. H01L 27/11578; H01L 27/11521; H01L 27/11551; H01L 27/11568

(52) U.S. Cl. CPC H01L 27/11578; H01L 27/11521; H01L 27/11551; H01L 27/11568

(57) ABSTRACT

A semiconductor device includes a substrate, a stacked body, a plurality of columnar semiconductors, a semiconductor layer, and a conductive portion. The stacked body is placed above the substrate. The stacked body includes a plurality of conductive layers stacked with an insulating layer placed therebetween. The plurality of columnar semiconductors pass through the stacked body. The semiconductor layer is placed above the substrate. The semiconductor layer is connected to bottoms of the columnar semiconductors. The semiconductor layer has a groove pattern in a region adjacent to the stacked body. The conductive portion fills the groove pattern and is in contact with a side surface of the semiconductor layer in the region. The conductive portion electrically connects the semiconductor layer to the substrate.

### CROSS-REFERENCE TO RELATED APPLICATION(S)

This application is based upon and claims the benefit of priority from Japanese Patent Application No. 2021-150451, filed Sep. 15, 2021, the entire contents of which are incorporated herein by reference.

### FIELD Embodiments described herein relate generally to a semiconductor device.

### BACKGROUND

In a semiconductor device production process, sometimes a stacked body configured with an insulating layer and a sacrifice layer which are alternately stacked more than once is formed, a hole passing through the stacked body is formed, and then a semiconductor film or the like is embedded in the hole. It is desirable to properly form a hole passing through a stacked body in order to properly produce a semiconductor device.

### DESCRIPTION OF THE DRAWINGS

FIG. 1 is a sectional view showing the configuration of a semiconductor device according to an at least one embodiment.

FIG. 2 is a sectional view showing a charge elimination structure in at least one embodiment.

FIG. 3 is a plan view showing the charge elimination structure in at least one embodiment.

FIG. 4 is a sectional view showing a method for producing the semiconductor device according to at least one embodiment.

FIG. 5 is a sectional view showing the method for producing the semiconductor device according to at least one embodiment.

FIG. 6 is a plan view showing a charge elimination structure in a first modification of the embodiment.

FIG. 7 is a plan view showing a charge elimination structure in a second modification of the embodiment.

FIG. 8 is a plan view showing a charge elimination structure in a third modification of the embodiment.

FIG. 9 is a plan view showing a charge elimination structure in a fourth modification of the embodiment.

FIG. 10 is a plan view showing a charge elimination structure in a fifth modification of the embodiment.

### DETAILED DESCRIPTION

Embodiments provide a semiconductor device suitable for proper formation of a hole.

In general, according to at least one embodiment, provided is a semiconductor device including a substrate, a stacked body, a plurality of columnar semiconductors, a semiconductor layer, and a conductive portion. The stacked body is placed above the substrate. The stacked body includes a plurality of conductive layers stacked with an insulating layer placed therebetween. The plurality of columnar semiconductors pass through the stacked body. The semiconductor layer is placed above the substrate. The semiconductor layer is connected to bottoms of the columnar semiconductors. The semiconductor layer has a groove pattern in a region adjacent to the stacked body. The conductive portion fills the groove pattern and is in contact with a side surface of the semiconductor layer in the region. The conductive portion electrically connects the semiconductor layer to the substrate.

Hereinafter, a semiconductor device according to an embodiment will be described in detail with reference to the drawings. The embodiment is not intended as a limitation.

### Embodiment

The configuration of a semiconductor device 1 according to an embodiment will be described. The semiconductor device 1 includes a semiconductor layer placed above a substrate with an insulating film placed between the semiconductor layer and the substrate. There is a possibility that the potential floats in this semiconductor layer and charge stays there. For this reason, the semiconductor device 1 has a structure that makes the charge staying in the semiconductor layer flow into the ground potential via the substrate. In the present specification, a structure that makes the charge staying in the semiconductor layer flow into the ground potential via the substrate will be referred to as a charge elimination structure.

A CMOS under Array (CUA) structure in which a peripheral circuit region is provided below a memory array region MR is sometimes adopted in the semiconductor device 1 to increase the degree of integration of the semiconductor device 1.

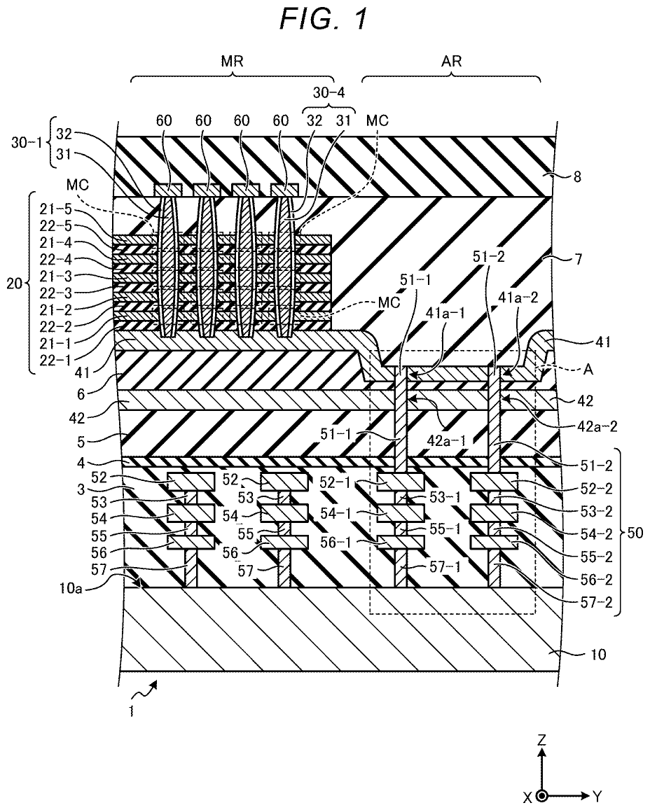

For example, the semiconductor device 1 is configured as shown in FIG. 1. FIG. 1 is a sectional view showing the configuration of the semiconductor device 1. The semiconductor device 1 includes a substrate 10, a stacked body 20, a plurality of columnar bodies 30-1 to 30-4, a semiconductor layer 41, a semiconductor layer 42, and a charge elimination structure 50. In the following description, a direction perpendicular to a front surface 10a of the substrate 10 is assumed to be a Z direction and two directions orthogonal to each other in a plane perpendicular to the Z direction are assumed to be an X direction and a Y direction.

The substrate 10 extends in the XY direction in the form of a flat plate. The substrate 10 is formed of a material containing a semiconductor (for example, silicon) as a main component. The semiconductor device 1 is three-dimensional memory, for example, and has a memory array region MR and an adjacent region AR. A plurality of memory cells are arranged in the XYZ direction in the memory array region MR. The adjacent region AR is adjacent to the memory array region MR in the XY direction. The substrate 10 extends over the memory array region MR and the adjacent region AR in the XY direction in the form of a flat plate.

The stacked body 20 is placed in the memory array region MR. The stacked body 20 is placed on the +Z side of the substrate 10 with insulating films 3 to 5 and 6 and so forth placed between the stacked body 20 and the substrate 10. The stacked body 20 includes a plurality of conductive layers 21-1 to 21-5 stacked with insulating layers 22 placed therebetween. An insulating layer 22-1, the conductive layer 21-1, an insulating layer 22-2, the conductive layer 21-2, an insulating layer 22-3, the conductive layer 21-3, an insulating layer 22-4, the conductive layer 21-4, an insulating layer 22-5, and the conductive layer 21-5 are stacked in order on a +Z-side surface of the semiconductor layer 41. The conductive layers 21-1 to 21-5 are formed of a conductive material. The conductive layers 21-1 to 21-5 may be formed of a substance containing metal (for example, tungsten) as a main component or a substance containing a semiconductor (for example, polysilicon) provided with conductivity as a main component. The insulating layers 22-1 to 22-5 are formed of an insulator. The insulating layers 22-1 to 22-5 may be formed of a substance containing semiconductor oxide (for example, silicon oxide) as a main component.

The plurality of columnar bodies 30-1 to 30-4 are placed in the memory array region MR. The plurality of columnar bodies 30-1 to 30-4 are arranged in the X direction and the Y direction. Each columnar body 30 has the shape of a column whose axis coincides with the Z direction, and extends in the Z direction and passes through the stacked body 20. Each columnar body 30 includes a columnar semiconductor 31 and an insulating film 32. The columnar semiconductor 31 extends in the Z direction and passes through the stacked body 20. A +Z-side end of the columnar semiconductor 31 is connected to a conductive film 60 and a −Z-side end is connected to the semiconductor layer 41. The insulating film 32 has the shape of a cylinder whose axis coincides with the Z direction, and extends in the Z direction on the outside of the columnar semiconductor 31 and passes through the stacked body 20.

In the memory array region MR, a plurality of memory cells arranged in the Z direction are located in positions at which the columnar semiconductor 31 and the plurality of conductive layers 21-1 to 21-5 intersect. A plurality of columnar semiconductors 31 are two-dimensionally arranged in the XY direction. As a result, a plurality of memory cells MC arranged in the XYZ direction are located at positions at which the plurality of columnar semiconductors 31 and the plurality of conductive layers 21-1 to 21-5 intersect. A +Z-side end of each of the columnar bodies 30-1 to 30-4 is connected to the conductive film 60. The conductive film 60 functions as a bit line. A plurality of conductive films 60 are covered with an insulating film 8 and insulated from each other. The conductive film 60 may be formed of a substance containing metal (for example, tungsten) as a main component. The insulating film 8 may be formed of a substance containing semiconductor oxide (for example, silicon oxide) as a main component.

The semiconductor layer 41 extends over the memory array region MR and the adjacent region AR in the XY direction in the form of a flat plate. The semiconductor layer 41 is covered with the stacked body 20 in the memory array region MR and is covered with an insulating film 7 in the adjacent region AR. The semiconductor layer 41 is formed of a substance containing a semiconductor provided with conductivity as a main component. A semiconductor provided with conductivity may be polysilicon containing n-type or p-type impurities, for example. The semiconductor layer 41 is connected to the −Z-side end of the columnar semiconductor 31 in the memory array region MR. The semiconductor layer 41 functions as a source line for the memory cell MC. The semiconductor layer 41 has groove patterns 41a-1 and 41a-2 in the adjacent region AR. The groove patterns 41a-1 and 41a-2 are separated from each other in the Y direction.

The semiconductor layer 41 is placed on the +Z side of the semiconductor layer 42 with the insulating film 6 placed between the semiconductor layer 41 and the semiconductor layer 42. The film thickness of the insulating film 6 in the adjacent region AR is smaller than the film thickness of the insulating film 6 in the memory array region MR. Consequently, the semiconductor layer 41 has a step near the boundary between the memory array region MR and the adjacent region AR, and the Z height of the semiconductor layer 41 above the substrate 10 in the adjacent region AR is lower than the Z height of the semiconductor layer 41 above the substrate 10 in the memory array region MR.

The semiconductor layer 42 extends over the memory array region MR and the adjacent region AR in the XY direction in the form of a flat plate. The semiconductor layer 42 is formed of a substance containing a semiconductor provided with conductivity as a main component. A semiconductor provided with conductivity may be polysilicon containing n-type or p-type impurities, for example. The semiconductor layer 42 has groove patterns 42a-1 and 42a-2 in the adjacent region AR. The groove patterns 42a-1 and 42a-2 are separated from each other in the Y direction. The groove patterns 42a-1 and 42a-2 correspond to the groove patterns 41a-1 and 41a-2. The groove patterns 42a-1 and 42a-2 may overlap with the groove patterns 41a-1 and 41a-2 when seen through from the Z direction.

The Z height of the semiconductor layer 42 above the substrate 10 in the memory array region MR is equal to the Z height of the semiconductor layer 42 above the substrate 10 in the adjacent region AR. Consequently, the Z direction distance between the semiconductor layer 41 and the semiconductor layer 42 in the adjacent region AR is shorter than the Z direction distance between the semiconductor layer 41 and the semiconductor layer 42 in the memory array region MR.

The charge elimination structure 50 is placed in the adjacent region AR. The charge elimination structure 50 electrically connects the semiconductor layers 41 and 42 and the substrate 10. As a result, when the substrate 10 is connected to the ground potential, the charge elimination structure 50 can make the charge accumulated in the semiconductor layer 41 flow into the ground potential via the substrate 10.

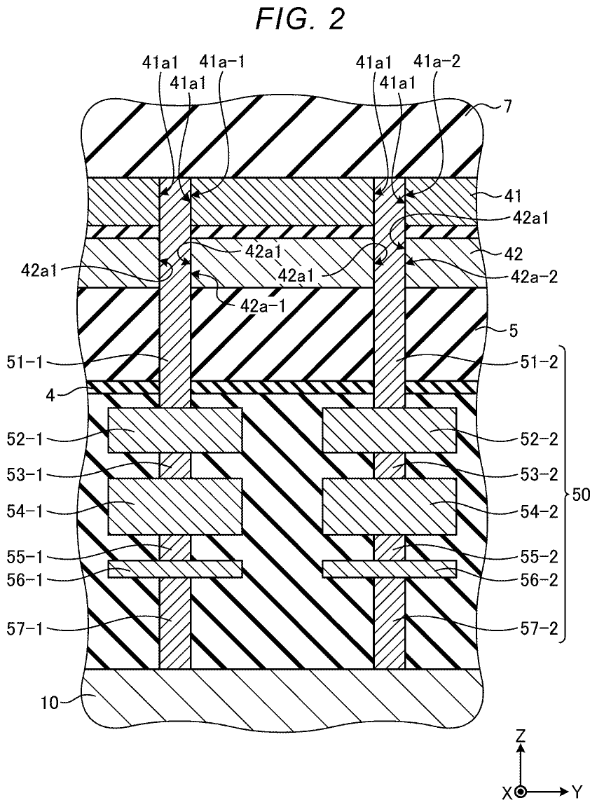

As shown in FIG. 2, the charge elimination structure 50 includes conductive portions 51-1 and 51-2, conductive films 52-1 and 52-2, conductive portions 53-1 and 53-2, conductive films 54-1 and 54-2, conductive portions 55-1 and 55-2, conductive films 56-1 and 56-2, and conductive portions 57-1 and 57-2. FIG. 2 is a YZ sectional view showing the charge elimination structure 50 and is an enlarged sectional view of a portion A of FIG. 1.

The conductive portions 51-1 and 51-2 electrically connect the semiconductor layer 41 and the semiconductor layer 42 to the conductive films 52-1 and 52-2. The conductive portions 51-1 and 51-2 fill the groove patterns 41a-1 and 41a-2 in the adjacent region AR. The conductive portions 51-1 and 51-2 are in contact with internal surfaces 41a1 of the groove patterns 41a-1 and 41a-2 of the semiconductor layer 41 and in contact with internal surfaces 42a1 of the groove patterns 42a-1 and 42a-2 of the semiconductor layer 42. When viewed in a YZ cross section, the conductive portions 51-1 and 51-2 extend from the groove patterns 41a-1 and 41a-2 to a side (−Z side) of the substrate 10 through the groove patterns 42a-1 and 42a-2 and are connected to the conductive films 52-1 and 52-2. Each of the conductive portions 51-1 and 51-2 may be formed of a conductive material such as a substance containing metal (for example, tungsten) as a main component.

A wiring structure that connects the conductive portion 51-1 to the substrate 10 is placed between the substrate 10 and the conductive portion 51-1. In this wiring structure, the conductive portion 57-1, the conductive film 56-1, the conductive portion 55-1, the conductive film 54-1, the conductive portion 53-1, and the conductive film 52-1 are stacked in order from the −Z side to the +Z side. Each of the conductive film 52-1, the conductive portion 53-1, the conductive film 54-1, the conductive portion 55-1, the conductive film 56-1, and the conductive portion 57-1 may be formed of a conductive material such as a substance containing metal (for example, aluminum, copper, or tungsten) as a main component. As a result, the conductive portion 51-1 electrically connects the semiconductor layer 41 and the semiconductor layer 42 to the substrate 10 via the conductive film 52-1, the conductive portion 53-1, the conductive film 54-1, the conductive portion 55-1, the conductive film 56-1, and the conductive portion 57-1.

Likewise, a wiring structure that connects the conductive portion 51-2 to the substrate 10 is placed between the substrate 10 and the conductive portion 51-2. In this wiring structure, the conductive portion 57-2, the conductive film 56-2, the conductive portion 55-2, the conductive film 54-2, the conductive portion 53-2, and the conductive film 52-2 are stacked in order from the −Z side to the +Z side. Each of the conductive film 52-2, the conductive portion 53-2, the conductive film 54-2, the conductive portion 55-2, the conductive film 56-2, and the conductive portion 57-2 may be formed of a conductive material such as a substance containing metal (for example, aluminum, copper, or tungsten) as a main component. As a result, the conductive portion 51-2 electrically connects the semiconductor layer 41 and the semiconductor layer 42 to the substrate 10 via the conductive film 52-2, the conductive portion 53-2, the conductive film 54-2, the conductive portion 55-2, the conductive film 56-2, and the conductive portion 57-2.

A conductive portion 57, a conductive film 56, a conductive portion 55, a conductive film 54, a conductive portion 53, and a conductive film 52 are also stacked in order from the −Z side to the +Z side between the substrate 10 and the insulating film 4 in the memory array region MR, whereby transistors with a CMOS structure and a wiring structure to make access thereto may be formed. These transistors may constitute a control circuit for controlling the plurality of memory cells MC. Each of the conductive portion 57, the conductive film 56, the conductive portion 55, the conductive film 54, the conductive portion 53, and the conductive film 52 may be formed of a conductive material such as a substance containing metal (for example, aluminum, copper, or tungsten) as a main component.

In the charge elimination structure 50, the conductive portions 51-1 and 51-2 are in contact with the semiconductor layer 41 and the semiconductor layer 42 on the side surfaces of the conductive portions 51-1 and 51-2. To reduce the resistance of a discharge path in the charge elimination structure 50, it is desirable to increase the area of contact between the conductive portion 51-1 and the semiconductor layers 41 and 42 and between the conductive portion 51-2 and the semiconductor layers 41 and 42.

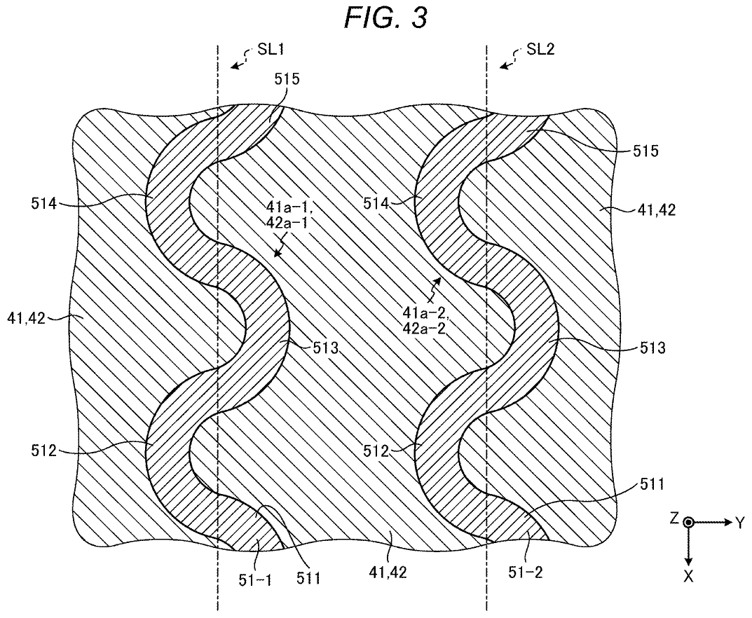

For this reason, as shown in FIG. 3, the groove pattern 41a-1 of the semiconductor layer 41 extends meandering with reference to a reference line SL1 when viewed in the XY plane. The groove pattern 42a-1 of the semiconductor layer 42 extends in a meandering fashion with reference to the reference line SL1 when viewed in the XY plane. Consequently, the conductive portion 51-1 extends in a meandering fashion with reference to the reference line SL1 when viewed in the XY plane. The reference line SL1 is an imaginary line and extends linearly in the X direction, for example.

Likewise, the groove pattern 41a-2 of the semiconductor layer 41 extends in a meandering fashion with reference to a reference line SL2 when viewed in the XY plane. The groove pattern 42a-2 of the semiconductor layer 42 extends in a meandering fashion with reference to the reference line SL2 when viewed in the XY plane. The conductive portion 51-2 extends in a meandering fashion with reference to the reference line SL2 when viewed in the XY plane. The reference line SL2 is an imaginary line and placed in a position shifted in the Y direction with respect to the reference line SL1, for example, and extends linearly in the X direction.

This allows the conductive portions 51-1 and 51-2 to increase the area of contact between the conductive portion 51-1 and the semiconductor layers 41 and 42 and between the conductive portion 51-2 and the semiconductor layers 41 and 42 as compared with a case where the conductive portions 51-1 and 51-2 extend linearly along the reference lines SL1 and SL2. That is, the conductive portions 51-1 and 51-2 can increase the area of contact between the conductive portion 51-1 and the semiconductor layers 41 and 42 and between the conductive portion 51-2 and the semiconductor layers 41 and 42 in the Z direction with no increase in footprint in the XY direction. FIG. 3 is an XY plan view showing the charge elimination structure 50 and is a plan view showing the front surface of the semiconductor layer 41 viewed from the +Z side. FIG. 3 illustrates a case where two lines of conductive portions are provided when viewed in the XY plane; the number of lines of conductive portions may be one or three or more.

The conductive portions 51-1 and 51-2 each have a plurality of curved portions 511 to 515 when viewed in the XY plane. The plurality of curved portions 511 to 515 are alternately placed on the +Y side and the −Y side of the reference line SL1 from the −X side to the +X side. The curved portion 511 is placed on the +Y side, the curved portion 512 is placed on the −Y side, the curved portion 513 is placed on the +Y side, the curved portion 514 is placed on the −Y side, and the curved portion 515 is placed on the +Y side.

The conductive portions 51-1 and 51-2 each have an outline on both sides (the +Y side and the −Y side) thereof that curves more than once from the −X side to the +X side. In the plurality of curved portions 511 to 515, a curve protruding to the +Y side and a curve protruding to the −Y side are alternately placed from the −X side to the +X side. The curved portion 511 curves and protrudes to the +Y side, the curved portion 512 curves and protrudes to the −Y side, the curved portion 513 curves and protrudes to the +Y side, the curved portion 514 curves and protrudes to the −Y side, and the curved portion 515 curves and protrudes to the +Y side. This allows the conductive portions 51-1 and 51-2 to prevent electric field concentration which occurs when a current flows and to extend in a meandering fashion with reference to the reference lines SL1 and SL2.

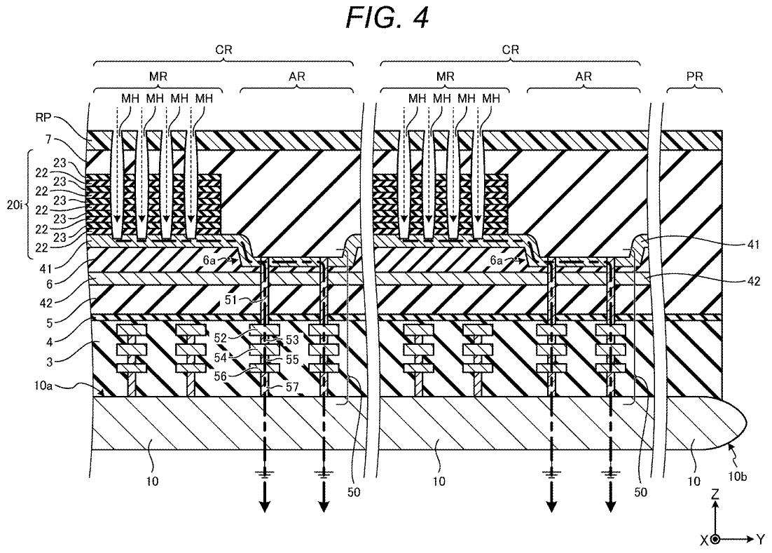

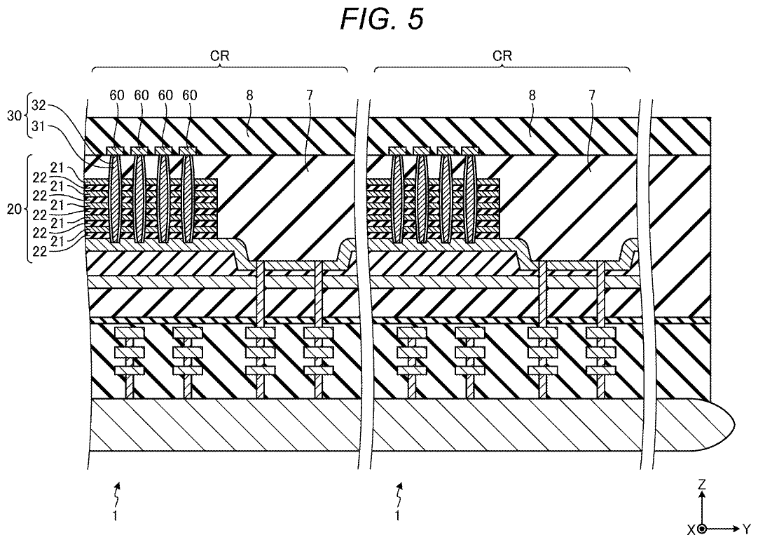

The semiconductor device 1 with the configuration shown in FIGS. 1 to 3 can be produced as shown in FIGS. 4 and 5. FIGS. 4 and 5 are each a sectional view showing a method for producing the semiconductor device 1.

In a process shown in FIG. 4, a substrate 10 is prepared. The substrate 10 has a plurality of chip regions CR and a peripheral region PR. Each chip region CR is a region where a pattern of a device is to be formed. Each chip region CR includes a memory array region MR and an adjacent region AR. The memory array region MR is a region where the arrangement of a plurality of memory cells is to be formed. The adjacent region AR is adjacent to the memory array region MR in the XY direction. The peripheral region PR is placed outside the plurality of chip regions CR. The substrate 10 has a bevel portion 10b, which is an edge in the XY direction, in the peripheral region PR.

A conductive portion 57, a conductive film 56, a conductive portion 55, a conductive film 54, a conductive portion 53, and a conductive film 52 are stacked in order on a +Z-side surface 10a of the substrate 10 and constitute a structure around which an insulating film 3 is placed. An insulating film 4, an insulating film 5, a semiconductor layer 42, an insulating film 6, and a semiconductor layer 41 are deposited in order on the +Z side of the insulating film 3.

A resist pattern having an opening corresponding to a groove pattern 41a (see FIG. 3) in the adjacent region AR is formed on the semiconductor layer 41. Etching is performed using the resist pattern as a mask, whereby a groove pattern passing through the semiconductor layer 41, the insulating film 6, the semiconductor layer 42, the insulating film 5, and the insulating film 4 and reaching the conductive film 52 is formed. That is, the groove pattern including a groove pattern 41a of the semiconductor layer 41 and a groove pattern 42a of the semiconductor layer 42 is formed.

A conductive material such as a material containing metal (for example, tungsten) as a main component is embedded in the groove pattern. As a result, a conductive portion 51 filling the groove pattern 41a of the semiconductor layer 41 and the groove pattern 42a of the semiconductor layer 42 and extending toward the substrate 10 and connected to the conductive film 52 is formed. That is, a charge elimination structure 50 electrically connecting the semiconductor layers 41 and 42 and the substrate 10 in the Z direction is formed.

A stacked body 20i including an insulating layer 22 and a sacrifice layer 23 which are alternately stacked more than once is formed on the semiconductor layer 41. The insulating layer 22 may be formed of an insulator such as silicon oxide. The sacrifice layer 23 may be formed of an insulator such as silicon nitride. The stacked body 20i is covered with an insulating film 7.

A resist pattern RP having a plurality of openings is formed on the insulating film 7. Each of the plurality of openings is formed in a region, where a columnar body 30 (see FIG. 1) is to be formed, in the resist pattern RP. Dry etching is performed using the resist pattern RP as a mask, whereby a plurality of memory holes MH are formed. Each of the plurality of memory holes MH is formed so as to pass through the stacked body 20i and reach the semiconductor layer 41.

Dry etching is performed by colliding etchant containing ions with a film being worked on; therefore, there is a possibility that charge accumulates in the semiconductor layer 41 when the hole being worked on extends through the stacked body 20i and reaches the semiconductor layer 41. There is a possibility that, when a state in which the semiconductor layer 41 is charged is maintained for a predetermined time or longer, arcing occurs in the semiconductor layer 41 and a pattern being worked on is damaged.

To address this problem, the charge elimination structure 50 electrically connecting the semiconductor layers 41 and 42 and the substrate 10 is formed. The substrate 10 is placed on a stage serving as an electrode of a dry etching apparatus and is electrically connected to the stage. As a result, as indicated in FIG. 4 by alternate long and short dashed lines, it is possible to discharge the charge in the semiconductor layer 41 via a path: the semiconductor layer 41→the charge elimination structure 50→the substrate 10→the stage→the reference potential (the power supply potential or the ground potential). This makes it possible to prevent arcing.

To prevent arcing, it might be another option to extend the semiconductor layer 41 to an area above the bevel portion 10b of the substrate 10 and form, in this area, a charge elimination structure that electrically connects the semiconductor layer 41 to the substrate 10 by a plug electrode or the like. This charge elimination structure allows a discharge current to flow from a charged portion in the semiconductor layer 41 to the area above the bevel portion 10b of the substrate 10 through the semiconductor layer 41 and to be discharged in this area from the semiconductor layer 41 toward the substrate 10. This results in a long discharge path, which makes parasitic resistance tend to be high; therefore, there is a possibility that a discharge current is less likely to flow and charge elimination is not satisfactorily performed. Moreover, at the time of production of this charge elimination structure, a pattern that extends the semiconductor layer 41 to an area above the bevel portion 10b of the substrate 10 is sometimes cut due to excessive polishing or the like, which also raises a possibility that a discharge current is less likely to flow and charge elimination is not satisfactorily performed with this charge elimination structure.

By contrast, with the charge elimination structure 50 of at least one embodiment, since the charge elimination structure 50 is provided for each chip region CR, it is possible to make shorter a discharge path for charge elimination with ease and achieve reliable charge elimination.

In a process shown in FIG. 5, a monocrystalline semiconductor layer (for example, a silicon layer) is formed in the bottom of the memory hole MH by selective epitaxial growth. An oxide film (for example, a silicon oxide film), a nitride film (for example, a silicon nitride film), and an oxide film (for example, a silicon oxide film) are deposited in order on the side surface and the bottom surface of the memory hole MH, whereby an insulating film 32 is formed, and, after the removal of the insulating film 32 on the bottom surface of the memory hole MH, a semiconductor film (for example, a polysilicon film) is deposited, whereby a columnar semiconductor 31 is formed. In the memory hole MH, a core insulating layer may be embedded inside the columnar semiconductor 31. In this way, a columnar body 30 is formed in the memory hole MH.

After the removal of the resist pattern RP, a slit (not shown in FIG. 5) is formed through a predetermined process, the sacrifice layer 23 in the stacked body 20i is removed by isotropic etching such as wet etching which is performed via the slit, and a conductive substance is embedded, via the slit, in a gap formed by the above removal, whereby a stacked body 20 configured with the alternately stacked conductive layers 21 and insulating layers 22 is formed.

Then, a conductive film 60 is patterned on the columnar body 30, an insulating film 8 covering the insulating film 7 and the conductive film 60 is formed, and a semiconductor wafer including the plurality of chip regions CR is obtained through a predetermined process. The semiconductor wafer is cut into pieces, each including one chip region CR, and the semiconductor device 1 shown in FIG. 1 is obtained.

As described above, in at least one embodiment, the semiconductor device 1 includes the charge elimination structure 50 in the adjacent region AR adjacent to the memory array region MR. In the charge elimination structure 50, the conductive portion 51 fills the groove pattern 41a of the semiconductor layer 41 and is in contact with the side surface of the semiconductor layer 41 in the adjacent region AR. The conductive portion 51 extends toward the substrate 10 from the groove pattern 41a and is electrically connected to the substrate 10. This makes it possible to provide, as a structure of the semiconductor device 1, a structure suitable for charge elimination of the semiconductor layer 41 at the time of the formation of the memory hole MH by dry etching.

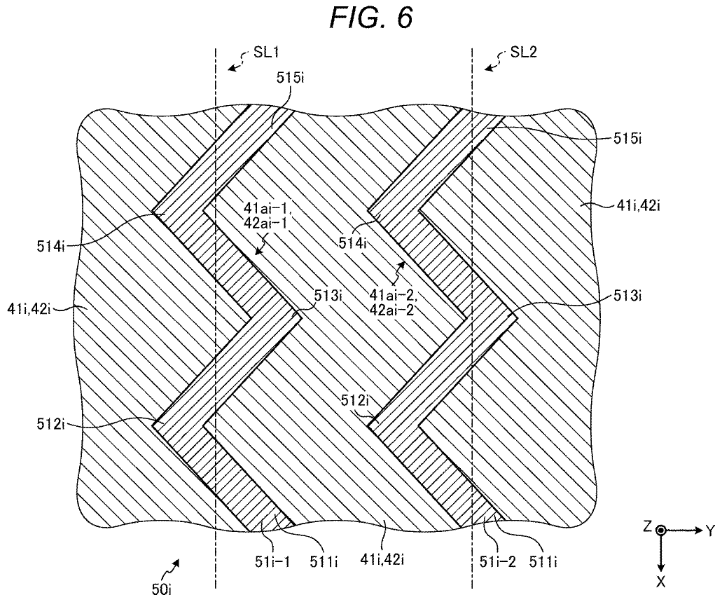

As shown in FIG. 6, a conductive portion 51i in a charge elimination structure 50i may extend zigzag when viewed in the XY plane. FIG. 6 is an XY plan view showing the charge elimination structure 50i and is a plan view showing the front surface of a semiconductor layer 41i viewed from the +Z side.

A groove pattern 41ai-1 of the semiconductor layer 41i extends zigzag with reference to a reference line SL1 when viewed in the XY plane. A groove pattern 42ai-1 of a semiconductor layer 42i extends zigzag with reference to the reference line SL1 when viewed in the XY plane. Consequently, a conductive portion 51i-1 extends zigzag with reference to the reference line SL1 when viewed in the XY plane.

Likewise, a groove pattern 41ai-2 of the semiconductor layer 41i extends zigzag with reference to a reference line SL2 when viewed in the XY plane. A groove pattern 42ai-2 of the semiconductor layer 42i extends zigzag with reference to the reference line SL2 when viewed in the XY plane. A conductive portion 51i-2 extends zigzag with reference to the reference line SL2 when viewed in the XY plane.

The conductive portions 51i-1 and 51i-2 each have a plurality of bent portions 511i to 515i when viewed in the XY plane. The plurality of bent portions 511i to 515i are alternately placed on the +Y side and the −Y side of the reference lines SL1 and SL2 from the −X side to the +X side. The bent portion 511i is placed on the +Y side, the bent portion 512i is placed on the −Y side, the bent portion 513i is placed on the +Y side, the bent portion 514i is placed on the −Y side, and the bent portion 515i is placed on the +Y side.

The conductive portions 51i-1 and 51i-2 each have an outline on both sides (the +Y side and the −Y side) thereof that bends more than once from the −X side to the +X side. In the plurality of bent portions 511i to 515i, a bend protruding to the +Y side and a bend protruding to the −Y side are alternately placed from the −X side to the +X side. The bent portion 511i bends and protrudes to the +Y side, the bent portion 512i bends and protrudes to the −Y side, the bent portion 513i bends and protrudes to the +Y side, the bent portion 514i bends and protrudes to the −Y side, and the bent portion 515i bends and protrudes to the +Y side. This allows the conductive portions 51i-1 and 51i-2 to extend zigzag with reference to the reference lines SL1 and SL2.

This configuration also allows the conductive portions 51i-1 and 51i-2 to increase the area of contact between the conductive portion 51i-1 and the semiconductor layers 41i and 42i and between the conductive portion 51i-2 and the semiconductor layers 41i and 42i as compared with a case where the conductive portions 51i-1 and 51i-2 extend linearly along the reference lines SL1 and SL2. That is, the conductive portions 51i-1 and 51i-2 can increase the area of contact between the conductive portion 51i-1 and the semiconductor layers 41i and 42i and between the conductive portion 51i-2 and the semiconductor layers 41i and 42i in the Z direction with no increase in footprint in the XY direction.

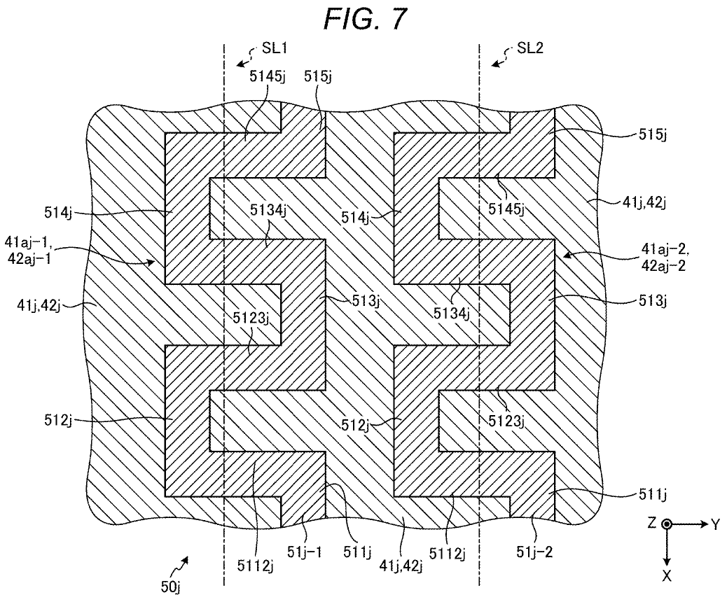

Alternatively, as shown in FIG. 7, a conductive portion 51j in a charge elimination structure 50j may extend in a meandering fashion when viewed in the XY plane. FIG. 7 is an XY plan view showing the charge elimination structure 50j and is a plan view showing the front surface of a semiconductor layer 41j viewed from the +Z side.

A groove pattern 41aj-1 of the semiconductor layer 41j extends meanderingly with reference to a reference line SL1 when viewed in the XY plane. A groove pattern 42aj-1 of a semiconductor layer 42j extends meanderingly with reference to the reference line SL1 when viewed in the XY plane. Consequently, a conductive portion 51j-1 extends meanderingly with reference to the reference line SL1 when viewed in the XY plane.

Likewise, a groove pattern 41aj-2 of the semiconductor layer 41j extends meanderingly with reference to a reference line SL2 when viewed in the XY plane. A groove pattern 42aj-2 of the semiconductor layer 42j extends meanderingly with reference to the reference line SL2 when viewed in the XY plane. A conductive portion 51j-2 extends meanderingly with reference to the reference line SL2 when viewed in the XY plane.

The conductive portions 51j-1 and 51j-2 each have a plurality of straight-line portions 511j to 515j and connecting portions 5112j to 5145j when viewed in the XY plane. The plurality of straight-line portions 511j to 515j are alternately placed on the +Y side and the −Y side of the reference lines SL1 and SL2 from the −X side to the +X side. The straight-line portion 511j is placed on the +Y side, the straight-line portion 512j is placed on the −Y side, the straight-line portion 513j is placed on the +Y side, the straight-line portion 514j is placed on the −Y side, and the straight-line portion 515j is placed on the +Y side. The connecting portions 5112j to 5145j are placed in positions overlapping with the reference lines SL1 and SL2.

The straight-line portion 511j extends in a −X direction. The connecting portion 5112j extends in a −Y direction from a −X-side end of the straight-line portion 511j. The connecting portion 5112j crosses the reference lines SL1 and SL2 in the −Y direction and extends to a +X-side end of the straight-line portion 512j. The straight-line portion 512j extends in the −X direction. The connecting portion 5123j extends in a +Y direction from a −X-side end of the straight-line portion 512j. The connecting portion 5123j crosses the reference lines SL1 and SL2 in the +Y direction and extends to a +X-side end of the straight-line portion 513j. The straight-line portion 513j extends in the −X direction. The connecting portion 5134j extends in the −Y direction from a −X-side end of the straight-line portion 513j. The connecting portion 5134j crosses the reference lines SL1 and SL2 in the −Y direction and extends to a +X-side end of the straight-line portion 514j. The straight-line portion 514j extends in the −X direction. The connecting portion 5145j extends in the +Y direction from a −X-side end of the straight-line portion 514j. The connecting portion 5145j crosses the reference lines SL1 and SL2 in the +Y direction and extends to a +X-side end of the straight-line portion 515j. The straight-line portion 515j extends in the -X direction. This allows the conductive portions 51j-1 and 51j-2 to extend meanderingly with reference to the reference lines SL1 and SL2.

This configuration also allows the conductive portions 51j-1 and 51j-2 to increase the area of contact between the conductive portion 51j-1 and the semiconductor layers 41j and 42j and between the conductive portion 51j-2 and the semiconductor layers 41j and 42j as compared with a case where the conductive portions 51j-1 and 51j-2 extend linearly along the reference lines SL1 and SL2. That is, the conductive portions 51j-1 and 51j-2 can increase the area of contact between the conductive portion 51j-1 and the semiconductor layers 41j and 42j and between the conductive portion 51j-2 and the semiconductor layers 41j and 42j in the Z direction with no increase in footprint in the XY direction.

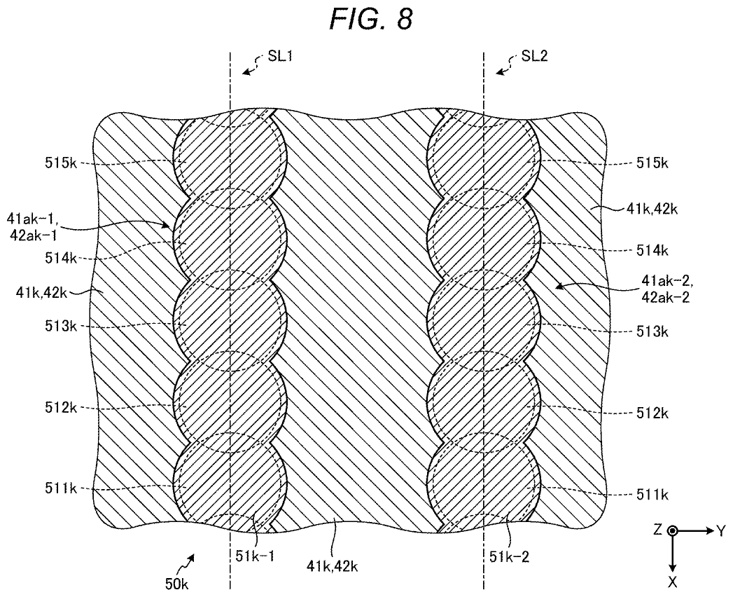

Alternatively, as shown in FIG. 8, a conductive portion 51k in a charge elimination structure 50k may have a shape in which a plurality of circles or ellipses are continuously connected when viewed in the XY plane. FIG. 8 is an XY plan view showing the charge elimination structure 50k and is a plan view showing the front surface of a semiconductor layer 41k viewed from the +Z side.

A groove pattern 41ak-1 of the semiconductor layer 41k has a shape in which a plurality of circles or ellipses are continuously connected when viewed in the XY plane and extends approximately in the X direction along a reference line SL1. A groove pattern 42ak-1 of a semiconductor layer 42k has a shape in which a plurality of circles or ellipses are continuously connected when viewed in the XY plane and extends approximately in the X direction along the reference line SL1. Consequently, a conductive portion 51k-1 has a shape in which a plurality of circles or ellipses are continuously connected when viewed in the XY plane and extends approximately in the X direction along the reference line SL1.

Likewise, a groove pattern 41ak-2 of the semiconductor layer 41k has a shape in which a plurality of circles or ellipses are continuously connected when viewed in the XY plane and extends approximately in the X direction along a reference line SL2. A groove pattern 42ak-2 of the semiconductor layer 42k has a shape in which a plurality of circles or ellipses are continuously connected when viewed in the XY plane and extends approximately in the X direction along the reference line SL2. Consequently, a conductive portion 51k-2 has a shape in which a plurality of circles or ellipses are continuously connected when viewed in the XY plane and extends approximately in the X direction along the reference line SL2.

The conductive portions 51k-1 and 51k-2 each have a shape in which a plurality of circles 511k to 515k are continuously connected from the +X side to the −X side along the reference lines SL1 and SL2. FIG. 8 illustrates a shape in which the plurality of circles 511k to 515k are continuously connected; the conductive portions 51k-1 and 51k-2 may have a shape in which a plurality of ellipses are continuously connected. The centers of the circles 511k to 515k are located in positions that are close to the reference lines SL1 and SL2 and are shifted from each other in the X direction. The distance between the centers of two adjacent circles: the circle 511k and the circle 512k is slightly smaller than the diameter of each circle. Consequently, a −X-side end of the circle 511k and a +X-side end of the circle 512k overlap one another. Likewise, the distance between the centers of two adjacent circles: the circle 514k and the circle 515k is slightly smaller than the diameter of each circle. Consequently, a −X-side end of the circle 514k and a +X-side end of the circle 515k overlap one another.

A −Y-side outline of the conductive portion 51k-1 extends approximately in the X direction, forming a plurality of concave and convex portions on the -Y side of the reference line SL1, and a −Y-side outline of the conductive portion 51k-2 extends approximately in the X direction, forming a plurality of concave and convex portions on the −Y side of the reference line SL2. A +Y-side outline of the conductive portion 51k-1 extends approximately in the X direction, forming a plurality of concave and convex portions on the +Y side of the reference line SL1, and a +Y-side outline of the conductive portion 51k-2 extends approximately in the X direction, forming a plurality of concave and convex portions on the +Y side of the reference line SL2.

This configuration also allows the conductive portions 51k-1 and 51k-2 to increase the area of contact between the conductive portion 51k-1 and the semiconductor layers 41k and 42k and between the conductive portion 51k-2 and the semiconductor layers 41k and 42k as compared with a case where the conductive portions 51k-1 and 51k-2 extend linearly along the reference lines SL1 and SL2. That is, the conductive portions 51k-1 and 51k-2 can increase the area of contact between the conductive portion 51k-1 and the semiconductor layers 41k and 42k and between the conductive portion 51k-2 and the semiconductor layers 41k and 42k in the Z direction with no increase in footprint in the XY direction.

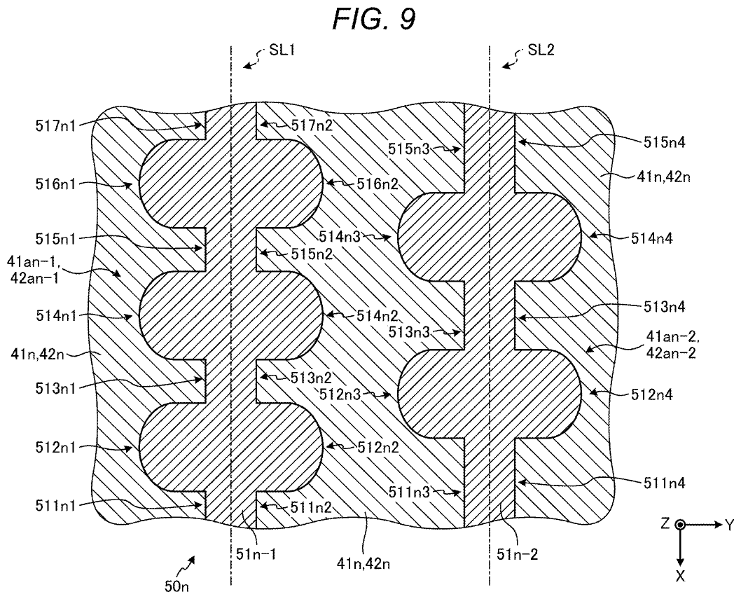

Alternatively, as shown in FIG. 9, a conductive portion 51n in a charge elimination structure 50n may include a plurality of concave and convex portions on both sides of a reference line when viewed in the XY plane. FIG. 9 is an XY plan view showing the charge elimination structure 50n and is a plan view showing the front surface of a semiconductor layer 41n viewed from the +Z side.

A groove pattern 41an-1 of the semiconductor layer 41n extends approximately in the X direction along a reference line SL1 so as to include a plurality of concave and convex portions on both sides of the reference line SL1 when viewed in the XY plane. A groove pattern 42an-1 of a semiconductor layer 42n extends approximately in the X direction along the reference line SL1 so as to include a plurality of concave and convex portions on both sides of the reference line SL1 when viewed in the XY plane.

Consequently, a conductive portion 51n-1 extends approximately in the X direction along the reference line SL1 so as to include a plurality of concave and convex portions on both sides of the reference line SL1 when viewed in the XY plane.

Likewise, a groove pattern 41an-2 of the semiconductor layer 41n extends approximately in the X direction along a reference line SL2 so as to include a plurality of concave and convex portions on both sides of the reference line SL2 when viewed in the XY plane. A groove pattern 42an-2 of the semiconductor layer 42n extends approximately in the X direction along the reference line SL2 so as to include a plurality of concave and convex portions on both sides of the reference line SL2 when viewed in the XY plane. Consequently, a conductive portion 51n-2 extends approximately in the X direction along the reference line SL2 so as to include a plurality of concave and convex portions on both sides of the reference line SL2 when viewed in the XY plane.

In a −Y-side portion of the conductive portion 51n-1, a concave portion 511n1, a convex portion 512n1, a concave portion 513n1, a convex portion 514n1, a concave portion 515n1, a convex portion 516n1, and a concave portion 517n1 are placed in order from the +X side to the −X side along the reference line SL1. In a +Y-side portion of the conductive portion 51n-1, a concave portion 511n2, a convex portion 512n2, a concave portion 513n2, a convex portion 514n2, a concave portion 515n2, a convex portion 516n2, and a concave portion 517n2 are placed in order from the +X side to the −X side along the reference line SL1. FIG. 9 illustrates a case where a plurality of concave and convex parts in the conductive portion 51n-1 are approximately line symmetric with respect to the reference line SL1; the plurality of concave and convex parts in the conductive portion 51n-1 may be asymmetrical with respect to the reference line SL1.

In a −Y-side portion of the conductive portion 51n-2, a concave portion 511n3, a convex portion 512n3, a concave portion 513n3, a convex portion 514n3, and a concave portion 515n3 are placed in order from the +X side to the −X side along the reference line SL2. In a +Y-side portion of the conductive portion 51n-2, a concave portion 511n4, a convex portion 512n4, a concave portion 513n4, and a convex portion 514n4 are placed in order from the +X side to the −X side along the reference line SL2. FIG. 9 illustrates a case where a plurality of concave and convex parts in the conductive portion 51n-2 are approximately line symmetric with respect to the reference line SL2; the plurality of concave and convex parts in the conductive portion 51n-2 may be asymmetrical with respect to the reference line SL2.

Moreover, as shown in FIG. 9, the plurality of concave and convex parts in the conductive portion 51n-1 and the plurality of concave and convex parts in the conductive portion 51n-2 may be placed in an arrangement in which they engage each other. For example, the X position of the convex portion 512n2 and the X position of the concave portion 511n3 virtually coincide. The X position of the concave portion 513n2 and the X position of the convex portion 512n3 virtually coincide. The X position of the convex portion 514n2 and the X position of the concave portion 513n3 virtually coincide. The X position of the concave portion 515n2 and the X position of the convex portion 514n3 virtually coincide. The X position of the convex portion 516n2 and the X position of the concave portion 515n3 virtually coincide.

This configuration also allows the conductive portions 51n-1 and 51n-2 to increase the area of contact between the conductive portion 51n-1 and the semiconductor layers 41n and 42n and between the conductive portion 51n-2 and the semiconductor layers 41n and 42n as compared with a case where the conductive portions 51n-1 and 51n-2 extend linearly along the reference lines SL1 and SL2. That is, the conductive portions 51n-1 and 51n-2 can increase the area of contact between the conductive portion 51n-1 and the semiconductor layers 41n and 42n and between the conductive portion 51n-2 and the semiconductor layers 41n and 42n in the Z direction with no increase in footprint in the XY direction.

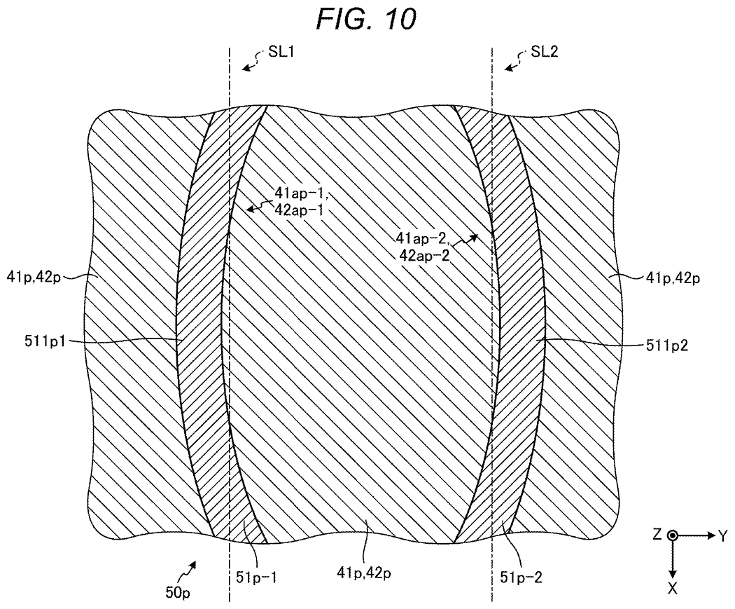

Alternatively, as shown in FIG. 10, a conductive portion 51p in a charge elimination structure 50p may extend in an arc when viewed in the XY plane. FIG. 10 is an XY plan view showing the charge elimination structure 50p and is a plan view showing the front surface of a semiconductor layer 41p viewed from the +Z side.

A groove pattern 41ap-1 of the semiconductor layer 41p extends in an arc so as to cross a reference line SL1 when viewed in the XY plane. A groove pattern 42ap-1 of a semiconductor layer 42p extends in an arc so as to cross the reference line SL1 when viewed in the XY plane. Consequently, a conductive portion 51p-1 extends in an arc so as to cross the reference line SL1 when viewed in the XY plane.

Likewise, a groove pattern 41ap-2 of the semiconductor layer 41p extends in an arc so as to cross a reference line SL2 when viewed in the XY plane. A groove pattern 42ap-2 of the semiconductor layer 42p extends in an arc so as to cross the reference line SL2 when viewed in the XY plane. Consequently, a conductive portion 51p-2 extends in an arc so as to cross the reference line SL2 when viewed in the XY plane.

The conductive portion 51p-1 has a curved portion 511p1 when viewed in the XY plane. The curved portion 511p1 is placed on the −Y side of the reference line SL1 near the center in the X direction.

The conductive portion 51p-2 has a curved portion 511p2 when viewed in the XY plane. The curved portion 511p2 is placed on the +Y side of the reference line SL2 near the center in the X direction.

The curved portion 511p1 has an outline on both sides (the +Y side and the −Y side) thereof that curves once from the −X side to the +X side. The curved portion 511p1 curves and protrudes to the −Y side from the −X side to the +X side. This allows the conductive portion 51p-1 to extend in an arc so as to cross the reference line SL1 when viewed in the XY plane.

The curved portion 511p2 has an outline on both sides (the +Y side and the −Y side) thereof that curves once from the −X side to the +X side. The curved portion 511p2 curves and protrudes to the +Y side from the −X side to the +X side. This allows the conductive portion 51p-2 to extend in an arc so as to cross the reference line SL2 when viewed in the XY plane.

Both the curved portion 511p1 and the curved portion 511p2 may curve and protrude to the -Y side or curve and protrude to the +Y side.

This configuration also allows the conductive portions 51p-1 and 51p-2 to increase the area of contact between the conductive portion 51p-1 and the semiconductor layers 41p and 42p and between the conductive portion 51p-2 and the semiconductor layers 41p and 42p as compared with a case where the conductive portions 51p-1 and 51p-2 extend linearly along the reference lines SL1 and SL2. That is, the conductive portions 51p-1 and 51p-2 can increase the area of contact between the conductive portion 51p-1 and the semiconductor layers 41p and 42p and between the conductive portion 51p-2 and the semiconductor layers 41p and 42p in the Z direction with no increase in footprint in the XY direction.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a substrate;
a stacked body disposed above the substrate and including a plurality of conductive layers stacked with an insulating layer disposed between the conductive layers;
a plurality of columnar semiconductors extending through the stacked body in a first direction, the first direction perpendicular to a first plane;
a semiconductor layer disposed above the substrate, the semiconductor layer connected to bottoms of the columnar semiconductors, and having a groove pattern in a region adjacent to the stacked body; and
a conductive portion filling the groove pattern, being in contact with a side surface of the semiconductor layer in the region, and electrically connecting the semiconductor layer to the substrate.

2. The semiconductor device according to claim 1,
wherein the conductive portion extends in a non-linear fashion with reference to a reference line when viewed in the first plane.

3. The semiconductor device according to claim 1,
wherein the conductive portion includes a curved portion when viewed along the first plane.

4. The semiconductor device according to claim 1,
wherein the conductive portion includes a plurality of curved portions when viewed along the first plane.

5. The semiconductor device according to claim 1,
wherein the conductive portion includes a plurality of bent portions when viewed along the first plane.

6. The semiconductor device according to claim 1,
wherein the conductive portion has a shape of a plurality of circles or ellipses continuously connected when viewed along the first plane.

7. The semiconductor device according to claim 1,
wherein the conductive portion includes a plurality of concave and convex portions extending on both sides of a reference line when viewed along the first plane.

8. The semiconductor device according to claim 1, further comprising:
a wiring structure disposed between the conductive portion and the substrate in a stacking direction, the wiring structure electrically connecting the conductive portion to the substrate.

9. The semiconductor device according to claim 1,
wherein the conductive portion is disposed around the stacked body when viewed along the first plane.

10. The semiconductor device according to claim 1, further comprising:
a charge elimination structure disposed between the conductive portion and the substrate in a stacking direction, the charge elimination structure electrically connecting the conductive portion to the substrate.

11. The semiconductor device according to claim 1, further comprising a plurality of memory cells, wherein the semiconductor layer is a source line connected to the plurality of memory cells.

12. The semiconductor device according to claim 1, wherein the semiconductor layer has a step adjacent a boundary between a memory region and an adjacent region adjacent to the memory region.

13. The semiconductor device according to claim 1, wherein the semiconductor layer includes polycrystalline silicon material.

14. The semiconductor device according to claim 1, wherein the substrate includes a semiconductor material.

15. The semiconductor device according to claim 1, wherein the semiconductor device is a three-dimensional memory device.

16. The semiconductor device according to claim 1,
wherein the conductive portion includes a plurality of arc shaped portions when viewed along the first plane.
